(19) United States
(12) Patent Application Publication
(10) Pub. No.: US 2025/0169082 A1
(43) Pub. Date: May 22, 2025

(54) ELECTROCHEMICAL MEMORY CELL AND NEURAL NETWORK MEMORY INCLUDING THE SAME

(71) Applicant: SK hynix Inc., Icheon-si (KR)

(72) Inventors: Won Tae KOO, Icheon-si (KR); Pil Hoon JUNG, Icheon-si (KR)

(21) Appl. No.: 18/433,859

(22) Filed: Feb. 6, 2024

(30) Foreign Application Priority Data
Nov. 20, 2023 (KR) 10-2023-0160371

(51) Int. Cl. H10B 69/00; H01L 29/78; H10B 99/00

(52) U.S. Cl. CPC H10B 69/00; H10B 99/22; H10D 30/6211

(57) ABSTRACT

An electrochemical memory cell may include an electrochemical channel, a gate and an interface layer. The electrochemical channel may include a protruded surface having a fin-shape. The gate may be overlapped with the protruded surface of the electrochemical channel. The interface layer may be formed between the protruded surface of the electrochemical channel and the gate. The interface layer may control ion exchanges for memory operations between the gate and the electrochemical channel based on a gate voltage.

### CROSS-REFERENCE TO RELATED APPLICATION

The present application claims priority under 35 U.S.C. § 119 (a) to Korean application number 10-2023-0160371 filed on Nov. 20, 2023, in the Korean Intellectual Property Office, which is incorporated herein by reference in its entirety.

### BACKGROUND

### 1. Technical Field

Various embodiments generally relate to a semiconductor memory technology, more particularly, to an electrochemical memory cell and a neural network memory device including the same.

### 2. Related Art

In von Neumann computer architecture, frequent movements of massive data between a processor and a memory may cause long delay times and high-power consumption. In order to solve these problems, an analog cross point array structure may be proposed.

The analog cross point array may include a plurality of memory cells programmed by a plurality of conductance. The analog cross point may calculate a vector-matrix multiplication and a vector outer product update using a time complexity in an analog way.

A non-volatile memory may be mainly used for a memory cell of an analog cross point array. Recently, as artificial synapse weights in the artificial neural network memory device become increasingly important, an electrochemical random access memory (ECRAM) may be widely used for the memory cell of an analog cross point array.

The electrochemical memory cell may perform a memory operation by an ion exchange with a channel in accordance with a gate voltage (or a gate current).

However, as the integration degree of a semiconductor memory device increases, the size of the electrochemical memory cell may need to be reduced. Further, it may be required to secure an accurate ratio between a set resistance and a reset resistance and rapid operation characteristics in the electrochemical memory cell.

### SUMMARY

According to example embodiments, there may be provided an electrochemical memory cell. The electrochemical memory cell may include an electrochemical channel, a gate and an interface layer. The electrochemical channel may include a protrusion surface having a fin-shape. The gate may overlap with the protrusion surface of the electrochemical channel. The interface layer may be formed between the protrusion surface of the electrochemical channel and the gate. The interface layer may control ion exchanges for memory operations between the gate and the electrochemical channel based on a gate voltage.

According to example embodiments, there may be provided an electrochemical memory cell. The electrochemical memory cell may include an electrochemical fin structure, a gate, a source, a drain, an electrolyte layer and an ion storage layer. The electrochemical fin structure may be protruded from a surface of a lower layer. The gate may be overlapped with a channel region of the electrochemical fin structure. The source may be formed in the electrochemical fin structure at one side of the gate. The drain may be formed in the electrochemical fin structure at the other side of the gate. The electrolyte layer may be positioned between the channel region and the gate. The electrolyte layer may make contact with both sidewalls and an upper surface of the protruded channel region. The ion storage layer may be formed between the electrolyte layer and the gate to generate and receive ions for memory operations together with the gate. The electrolyte layer may selectively provide the ions to the channel region through both sidewalls and the upper surface of the channel region based on a gate voltage.

According to example embodiments, there may be provided a neural network memory device. The neural network memory device may include a plurality of word lines, a plurality of bit lines, a plurality of source lines and an electrochemical memory cell. The word lines may be extended parallel to each other in a first direction. The bit lines may be extended parallel to each other in a second direction intersected with the first direction. The source lines may be extended parallel to at least one of the first direction and the second direction.

The electrochemical memory cell may be arranged at intersected portions between the word lines, the bit lines and the source lines.

The electrochemical memory cell may include an electrochemical fin structure, a gate, a source, a drain and an electrolyte layer. The electrochemical fin structure may be protruded. The gate may be overlapped with a channel region of the electrochemical fin structure. The gate may be electrically connected with any one selected from the plurality of word lines. The source may be formed in the electrochemical fin structure at one side of the gate. The source may be electrically connected with any one selected from the plurality of source lines. The drain may be formed in the electrochemical fin structure at the other side of the gate. The drain may be electrically connected with any one selected from the plurality of bit lines. The electrolyte layer may be positioned between the channel region and the gate. The electrolyte layer may make contact with both sidewalls and an upper surface of the protruded channel region.

According to example embodiments, the electrochemical memory cell having the fin structure may be used for the memory cell of the neural network memory device. Thus, the neural network memory device may have improved integration density and improved on/off characteristics.

Further, the ions may be rapidly exchanged through the protruded portion of the fin channel overlapped with the gate. The ions introduced over a large surface area may rapidly spread into the thin channel. Thus, the neural network memory device may have a rapid operation speed and low power consumption.

### BRIEF DESCRIPTION OF THE DRAWINGS

The above and other aspects, features and advantages of the subject matter of the present disclosure will be more clearly understood from the following detailed description taken in conjunction with the accompanying drawings, in which:

FIG. 1 is a circuit diagram illustrating a neural network memory device in accordance with an embodiment of the disclosure;

FIG. 2 is a perspective view illustrating an electrochemical memory cell in accordance with an embodiment of the disclosure;

FIGS. 3A and 3B are cross-sectional views illustrating a write operation of an electrochemical memory cell in accordance with an embodiment of the disclosure;

FIGS. 4A and 4B are cross-sectional views illustrating a read operation of an electrochemical memory cell in accordance with an embodiment of the disclosure;

FIG. 5 is a graph showing a conductance of a memory cell in accordance with an embodiment of the disclosure; and

FIG. 6 is a graph showing variances of a conductance of a memory cell in accordance with an embodiment of the disclosure.

### DETAILED DESCRIPTION

Various embodiments of the present disclosure will be described in greater detail with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes, which do not depart from the spirit and scope of the present invention as defined in the appended claims.

The present invention is described herein with reference to cross-section and/or plan illustrations of idealized embodiments of the present invention. However, embodiments of the present invention should not be construed as limiting the inventive concepts. Although a few embodiments of the present invention will be shown and described, it will be appreciated by those of ordinary skill in the art that changes may be made in these embodiments without departing from the principles and spirit of the present invention.

As used herein, the term “configured” refers to a size, shape, material composition, orientation, or arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to a major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, spatially relative terms, such as “beneath,” “below,” “bottom,” “under,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” may encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, the phrase “coupled to” and “connected to” refer to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

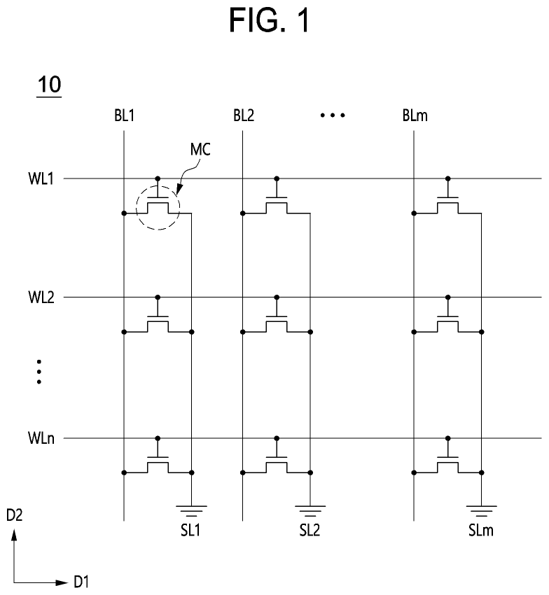

FIG. 1 is a circuit diagram illustrating a neural network memory device in accordance with an embodiment of the disclosure.

Referring to FIG. 1, a neural network memory device 10 of example embodiments may include a plurality of word lines WL1˜WLn and a plurality of bit lines BL1˜BLm that intersect the word lines WL1˜WLn. The neural network memory device 10 may further include a plurality of source lines SL1˜SLm.

For example, the plurality of word lines WL1˜WLn may be arranged parallel to each other in a first direction D1. The plurality of bit lines BL1˜BLm may be arranged parallel to each other in a second direction D2, which is substantially perpendicular to the first direction D1. The plurality of source lines SL1˜SLm may be extended in the first direction D1 or the second direction D2. In example embodiments, the plurality of source lines SL1˜SLm may be arranged in the second direction D2. Alternatively, the source lines SL1˜SLm may be commonly connected to a substrate bias line.

The neural network memory device 10 may include a plurality of memory cells MC. The plurality of memory cells MC may be arranged at intersecting portions of the plurality of word lines WL1˜WLn, the plurality of bit lines BL1˜BLm and the plurality of source lines SL1˜SLm, respectively.

Each of the memory cells MC may include three terminal type elements, respectively connected to one word line, one bit line and one source line. In example embodiments, the memory cell MC may have a switch and memory function including a gate, a drain and a source, as the three terminals. The gate may be electrically connected to a word line. The drain may be electrically connected to a bit line. The source may be electrically connected to a source line.

The gate may receive an operation voltage, such as program voltages for a set operation and a reset operation, and a read voltage. For example, a memory operation of the memory cell may be performed by resistance change of the memory cell according to an electrochemical reaction. The electrochemical reaction may be generated by ions that are generated in turn by the program voltages. The memory cells MC may be electrochemical memory cells. In the description below, the reference numeral MC may indicate an electrochemical memory cell.

The plurality of word lines WL1˜WLn may be connected to an input control block (not illustrated). A word line of a selected address may receive an operation voltage. The plurality of bit lines BL1˜BLm may be connected to an output control block (not illustrated) to sense a conductance of the memory cell at a selected address. A resistance of the memory cell MC may be determined by an output current from the memory cell MC. The resistance of the memory cell may mean a conductance of the memory cell MC.

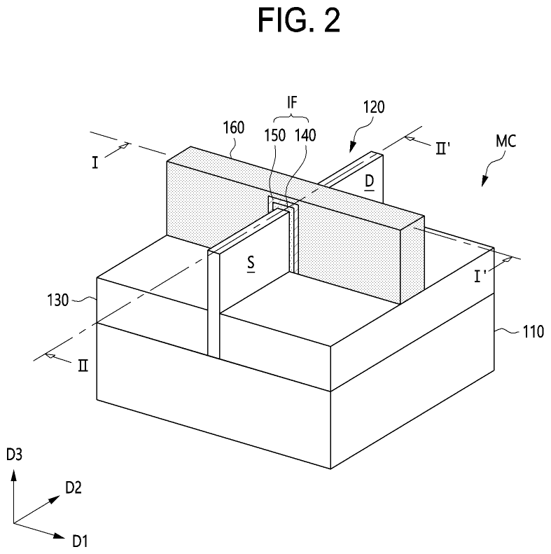

FIG. 2 is a perspective view illustrating an electrochemical memory cell in accordance with an embodiment of the disclosure.

Referring to FIG. 2, an electrochemical memory cell MC may be formed on a lower layer 110. The electrochemical memory cell MC may include an electrochemical fin structure 120 and a gate 160.

The lower layer 110 may include at least one semiconductor layer, a semiconductor substrate, and so forth. In example embodiments, the lower layer 110 may include a silicon layer, a single crystalline silicon substrate, and so forth. Alternatively, the lower layer 110 may include Ge, SiC, GaAs, GaP, InP, InAs, InSb, SiGe, GaAsP, AlInAs, AlGaAs, GaInAs, GaInP, GaInAsP, or a combination thereof. Further, the lower layer 110 may include a silicon-on-insulator (SOI) substrate, a silicon germanium-on-insulator (SGOI) substrate, or a germanium-on-insulator (GOI) substrate, and so forth.

The electrochemical fin structure 120 may protrude from an upper surface of the lower layer 110 in a third (vertical) direction D3. For example, the electrochemical fin structure 120 may have a height extending in the third direction D3, a width extending in the first direction D1, and a length extending in the second direction D2. In an example, the electrochemical fin structure 120 may include an active region of an electrochemical memory cell MC.

For example, the electrochemical fin structure 120 may include a source S, a channel (not shown) and a drain D. The channel may be defined by a portion of the electrochemical fin structure 120 that overlaps the gate 160. The source S may be positioned at one side of the channel. The drain D may be positioned at the other side of the channel. For example, the source S, the channel and the drain D may be arranged side by side along a lengthwise direction (that is, along the second direction D2) of the electrochemical fin structure 120. Further, the source S and the drain D may be separated from the gate 160. For example, the source S and the drain D may be insulated from the gate 160 by an insulation layer 130. The portion of the electrochemical fin structure 120 included in an active region of an electrochemical memory cell MC is thus a portion that extends from the insulation layer 130 in the D3 direction, and outer surfaces of the channel structure protrude from an upper surface of the insulation layer 130 and are covered by the gate 160. The channel may include a material having resistance change properties depending on a voltage applied to the gate 160, such as for example a gate voltage.

The gate 160 may overlap with the channel of the electrochemical fin structure 120. The gate 160 may extend in the first direction D1. In an embodiment, the gate 160 may be configured to surround the channel and the electrochemical fin structure 120 in areas where the gate 160 and the electrochemical fin structure 120 overlap in a plan view (i.e., viewed in the D3 direction). The gate 160 may include a conductive material such as a metal. For example, the gate 160 may generate and receive ions based on the gate voltage. Further, the gate 160 may be a part of a word line connected to a memory cell MC described above with reference to FIG. 1.

The electrochemical memory cell MC may include an interface layer IF between the channel and the gate 160. The interface layer IF may be formed along a surface of the channel. The interface layer IF may selectively control exchanges of ions in a memory operation based on the gate voltage.

For example, the interface layer IF may transfer the ions for a memory operation to the channel. Further, the interface layer IF may receive the ions for the memory operation from the channel or may block the transfer of the ions for the memory operation based on an electric field between the channel and the gate 160.

The interface layer IF may include an electrolyte layer 140. The electrolyte layer 140 may include an insulation material having a plurality of grain boundaries. The electrolyte layer 140 may exchange ions between the gate 160 and the channel in accordance with the gate voltage. Further, the electrolyte layer 140 may act as a barrier that prevents ion diffusion. Alternatively, the interface layer IF may further include an ion storage layer 150 interposed between the electrolyte layer 140 and the gate 160. The ion storage layer 150 may generate and receive ions together with the gate 160. For example, the ion storage layer 150 may generate an electrochemical reaction in accordance with the gate voltage to generate the ions. The ion storage layer 150 may store the ions in a non-program operation. The ion storage layer 150 may include a metal compound having an oxygen ion, which may be used as ions for the memory operation. In an embodiment, the ion storage layer may be a part of the gate 160.

Alternatively, at least one of the channel of the electrochemical fin structure 120, the gate 160, the electrolyte layer 140 and the ion storage layer 150 may include a material in which an electrochemical reaction occurs based on the gate voltage.

In an embodiment, the materials in the electrochemical fin structure 120, the electrolyte layer 140 and the ion storage layer 150 may be selected in accordance with ions suitable for a memory operation. The memory cell may operate differently depending on the kinds of the ions used with a memory operation.

For example, the ions used in memory operations may include O²⁻ ions, H⁺ ions and Li⁺ ions.

When the electrochemical fin structure 120, the electrolyte layer 140 and the ion storage layer 150 includes an oxygen-containing material, or a metal oxidation material, for instance, the ions used in a memory operation may include the O²⁻ ions. For example, the electrochemical fin structure 120 may include at least one of WO₃ and TiO₂. The electrolyte layer 140 may include at least one of HFOX, ZrO₂, yttria-stabilized zirconia (YSZ). The ion storage layer 150 may include at least one of Ta₂O₅, TiO₂ and WO₃.

When the electrochemical fin structure 120 includes at least one of WO₃ and 2D Mxene, for example, the ions used in a memory operation may include the H+ ions. The electrolyte layer 140 may include a liquid or an organic electrolyte material such as proton exchange membrane (PEM), nafion membrane, phosphosilicate glass (PSG), etc. The ion storage layer 150 may include at least one of Pd(Hx), Mg(Hx) and Y(YHx).

When the electrochemical fin structure 120 includes at least one of WO₃, Liₓ₋₁CO₂ and graphene, for example, the ions used in a memory operation may include the Lit ions. The electrolyte layer 140 may include an insulation material having Li.

In some embodiments, the gate 160 may be operated as the ion storage layer 150 and include ions for memory operations, and the electrochemical memory cell may not have a separate ion storage layer 150.

### Write Operation

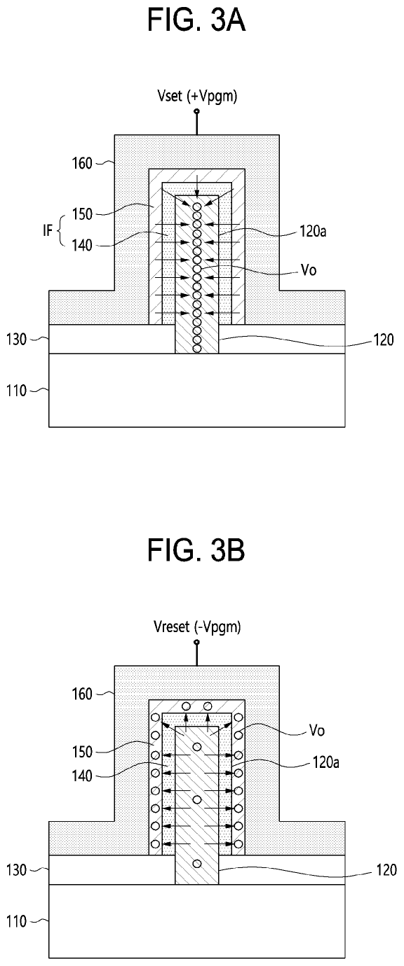

FIGS. 3A and 3B are cross-sectional views illustrating a write operation of an electrochemical memory cell in accordance with an embodiment of the disclosure. FIGS. 3A and 3B are cross-sectional views taken along a line I-I′ in FIG. 2. An interface layer IF in FIGS. 3A and 3B may use an electrolyte layer 140 and an ion storage layer 150. A memory operation of an electrochemical memory cell using oxygen vacancies as ions for a memory operation will be described below.

Referring to FIGS. 1, 2 and 3A, a positive program voltage +Vpgm, i.e., a set voltage Vset, may be applied to the gate 160. A ground voltage may be applied to the source S and the drain D. The set voltage Vset may be applied to the gate 160 through a selected word line. The lower layer 110 under the electrochemical fin structure 120 and a channel region between the source S and the drain D may maintain a ground voltage level.

The set voltage Vset may be a positive voltage higher than a threshold voltage for inducing an electrochemical reaction of the gate 160, the ion storage layer 150, the electrolyte layer 140 and a channel 120a.

When the set voltage Vset is applied to the gate 160, an electrochemical reaction may take place between the gate 160 and the ion storage layer 150 to generate ions from the ion storage layer 150 for a memory operation. In an embodiment, the ions for the memory operation may include an oxygen vacancy Vo.

An electric field may be generated between a gate 160, which may receive a set voltage Vset, and the source S and the drain D, which may receive a ground voltage. In accordance with the voltage difference and resulting electric field, the oxygen vacancies Vo in the ion storage layer 150 may be supplied to the channel 120a through the electrolyte layer 140. The amount of the oxygen vacancies in the channel 120a of the electrochemical fin structure 120 may increase so that the electrochemical memory cell may switch to a low resistance state, such as for example a set state.

As described above, surfaces of the channel 120a may protrude from the upper surface of the insulation layer 130, and the surfaces of the channel 120a, overlap with the gate 160. Thus, the protruded surfaces, i.e., both sidewalls and the upper surface of the channel 120a common to the gate 160, may be in contact with the interface layer IF and may exchange (both transfer and receive) ions for a memory operation. Because the channel 120a has a fin-like shape, the increase in surface area overlapping with a gate 160 in a three-dimensional (3D) electrochemical memory cell facilitates a faster exchange of the ions than an ion exchange in a two-dimensional (2D) electrochemical memory cell with a planar-type channel. As a result, the amount of time required to apply a set voltage may be reduced, resulting in lower power consumption and the rapid memory operation, and increased operation speed.

In embodiments, the channel 120a may have a fin or fin-like shape with a fine width to accommodate high integration density so that the channel 120a may be smaller, in terms of channel length and channel volume, than a channel of a 2D electrochemical memory cell.

Therefore, the ions for the memory operation may be transferred to the channel 120a, which may have a relatively small width, throughout the protruded surfaces. Thus, an electrochemical reaction may be rapidly generated in the channel 120a. As a result, after applying a program voltage, a channel resistance may be more rapidly changed compared to a program operation in a 2D electrochemical memory cell.

Referring to FIGS. 1 to 3B, a ground voltage may be applied to the source S and the drain D. A negative program voltage-Vpgm, i.e., a reset voltage Vreset, may be applied to the gate 160.

In an electrochemical reaction generated between the channel 120a, the electrolyte layer 140, the ion storage layer 150 and the gate 160 may reset an electric field in a manner opposite to the set operation between the channel 120a and the gate 160. The oxygen vacancies Vo in the channel 120a may be transferred to the ion storage layer 150 under the reset electric field. As the oxygen vacancies transfer from the channel 120a to the ion storage layer 150 (or the gate 160), a resistance of the channel 120a increases. Thus, the electrochemical memory cell may be switched to a high resistance state, that is, a reset state.

In embodiments, an electrochemical memory cell may be written to a low resistance state and a high resistance state by the exchange of the oxygen vacancies and the oxygen ions, but not other embodiments limited thereto. Alternatively, the electrochemical memory cell may use hydrogen ions or lithium ions as the ions used in the memory operation.

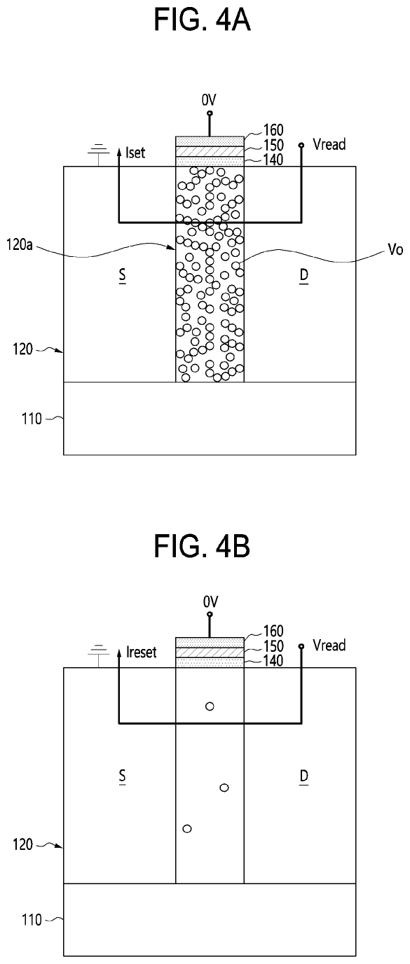

FIGS. 4A and 4B are cross-sectional views illustrating a read operation of an electrochemical memory cell in accordance with an embodiment of the disclosure. FIGS. 4A and 4B are cross-sectional views taken along a line II-II′ in FIG. 2. An interface layer IF in FIGS. 4A and 4B may use an electrolyte layer 140 and an ion storage layer 150.

Referring to FIGS. 1, 2, 3A, 4A and 4B, in order to measure a resistance of a channel 120a in an electrochemical memory cell, a voltage lower than the threshold voltage, for example about 0V, may be applied to a gate 160. A ground voltage may be applied to a source S. A read voltage Vread may be applied to a drain D. The read voltage Vread may generate a current from the drain D to the source S without changing the resistance of the channel 120a.

For example, as shown in FIGS. 3A and 4A, after oxygen vacancies Vo of the ion storage layer 150 are transferred to the channel 120a by applying a set voltage Vset, when the read voltage Vread is applied to the drain D, the electrochemical memory cell may output a current higher than a reference current because the resistance of the channel 120a is reduced by the increase in oxygen vacancies. Thus, the channel 120a may have a low resistance state. Further, the current may be determined as a set current Iset. For example, a sensing device (not shown) may read the set data of the electrochemical memory cell.

Referring to FIGS. 3B and 4B, after oxygen vacancies Vo of the channel 120a are transferred to the ion storage layer 150 by applying a reset voltage Vreset, when the read voltage Vread is applied to the drain D, the electrochemical memory cell may output a current lower than the reference current because the resistance of the channel 120a is increased by the reduction in oxygen vacancies Vo. Thus, the channel 120a may have a high resistance state. Further, the current may be determined as the reset current Ireset. For example, the sensing device (not shown) may read the reset data of the electrochemical memory cell.

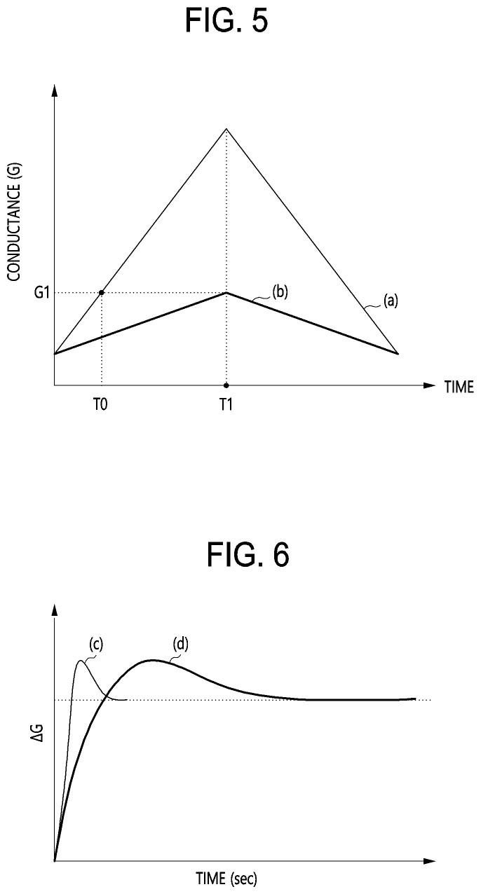

FIG. 5 is a graph showing a conductance G of a memory cell and FIG. 6 is a graph showing variances ΔG of a conductance G of a memory cell in accordance with an embodiment of the disclosure.

Referring to FIG. 5, under the same conditions, an operation voltage, such as a program voltage, may be applied to a gate of a 3D electrochemical memory cell (a) having a fin-shaped channel of an example embodiment and a gate of a 2D electrochemical memory cell (b) having a planar channel.

In embodiments, the ions for the memory operation may be transferred to the channel of the 3D electrochemical memory cell (a) across protruded surfaces of the fin-shaped channel that overlap with the gate. In some embodiments, the fin-shaped channel of a 3D electrochemical memory cell (a) may be smaller than a planar channel of the 2D electrochemical memory cell (b). Thus, the electrochemical reaction in the channel of disclosed embodiments may be generated more rapidly than the electrochemical reaction in the planer channel of the 2D electrochemical memory cell (b).

Therefore, it can be noted that a conductance G of the 3D electrochemical memory cell (a) with the fin-shaped channel of embodiments disclosed herein may be changed at a greater rate than a conductance G of the 2D electrochemical memory cell (b) with the planer channel.

That is, after lapsed a time T1, it can be noted that a conductance G of the 3D electrochemical memory cell (a) may be markedly increased compared to a conductance G of the 2D electrochemical memory cell (b).

Thus, when the same program voltage is applied over the same time period, it can be noted that a set/rest ratio (on/off efficiency) of the 3D electrochemical memory cell (a) is improved compared to that of the 2D electrochemical memory cell (b).

Further, as shown in FIG. 5, the 3D electrochemical memory cell (a) may reach the maximum conductance G1 of the 2D electrochemical memory cell (b) at a time TO, which is shorter than the time T1 for the 2D electrochemical memory cell (b) to reach the maximum conductance G1. Thus, the 3D electrochemical memory cell (a) may have faster operation speed than the 2D electrochemical memory cell (b). As a result, the 3D electrochemical memory cell (a) of example embodiments may be driven by lower amounts power.

As shown in FIG. 6, a variance ΔG of a conductance G in an 3D electrochemical memory cell (c) of embodiments may be rapidly changed compared to that of the 2D electrochemical memory cell (d). Thus, the 2D electrochemical memory cell (c) may have an operation speed that is faster than the operation speed of the 2D electrochemical memory cell (d).

In some embodiments, a memory cell of a neural network memory device may use an electrochemical memory cell with a 3D channel with a fin-shape or fin-like shape. A channel with a fin-shape may be a 3D-protruded shape and smaller than the size of a planar-type channel of the 2D electrochemical memory cell. Thus, the ions for a memory operation may be exchanged with each other through the all external surfaces of the channel with the fin-shape so that a change in resistance of the channel with the fin-shape may be rapidly generated in a short time. As a result, the on/off ratio of the channel with the fin-shape may be greatly increased to improve verification efficiency.

Further, the channel with the fin-shape may have the 3D-protruded size and space compared to the 2D planar-type channel to generate the various conductance changes.

Consequently, in order to induce a conductance substantially the same as a conductance of the 2D electrochemical memory cell, a lower program voltage may be used. Thus, the electrochemical memory cell of example embodiments may have relatively lower voltage drive and lower power consumption.

Furthermore, as shown in FIG. 6, the ion exchanges may be performed through the protruded surfaces in a limited space of a 3D electrochemical memory cell to improve the operation speed compared to the 2D electrochemical memory cell.

That is, in the 2D electrochemical memory cell, a reaction direction and a diffusion direction of the ions may be fixed to a direction substantially perpendicular to the channel. In contrast, in the 3D electrochemical memory cell, the ions may be transferred and diffuse along the horizontal direction, the vertical direction and angled directions between the horizontal and vertical to induce the rapid resistance change.

Moreover, the 3D protruded fin-shaped channel may function to decrease an occupying area of the memory cell to improve the integration density of the memory device.

The above described embodiments of the present invention are intended to illustrate and not to limit the present invention. Various alternatives and equivalents are possible. The invention is not limited by the embodiments described herein. Nor is the invention limited to any specific type of semiconductor device. Another additions, subtractions, or modifications are obvious in view of the present disclosure and are intended to fall within the scope of the appended claims.

What is claimed is:

1. An electrochemical memory cell comprising:
an electrochemical channel including a fin-shaped protrusion with a protrusion surface;
a gate overlapped with the fin-shaped protrusion; and
an interface layer, between the protrusion surface and the gate, configured to exchange ions between the gate and the electrochemical channel in a memory operation applying a gate voltage.

2. The electrochemical memory cell of claim 1, wherein the interface layer comprises an electrolyte layer that covers the protrusion surface.

3. The electrochemical memory cell of claim 2, wherein the interface layer further comprises an ion storage layer between the electrolyte layer and the gate that generates and receives the ions based on the gate voltage.

4. The electrochemical memory cell of claim 3, wherein the electrolyte layer comprises an insulation material.

5. The electrochemical memory cell of claim 3, wherein the ion storage layer comprises an ion component and a metal component.

6. The electrochemical memory cell of claim 1, further comprising:
a fin-shaped source formed at one side of the electrochemical channel; and
a fin-shaped drain formed at the other side of the electrochemical channel.

7. The electrochemical memory cell of claim 1, wherein at least one of the electrochemical channel, the gate and the interface layer comprises a material generating an electrochemical reaction based on the gate voltage.

8. An electrochemical memory cell comprising:
an electrochemical fin structure that protrudes from a lower layer;
a gate overlapped with a channel of the electrochemical fin structure;
a source formed in the electrochemical fin structure at one side of the gate;
a drain formed in the electrochemical fin structure at the other side of the gate;
an electrolyte layer between the channel and the gate that contacts sidewalls and an upper surface of the channel; and
an ion storage layer between the electrolyte layer and the gate that generates and receives ions based on a gate voltage,
wherein the electrolyte layer selectively provides the ions to the channel through the sidewalls and the upper surface of the channel based on the gate voltage.

9. The electrochemical memory cell of claim 8, wherein the electrolyte layer comprises an insulation material.

10. The electrochemical memory cell of claim 8, wherein the ion storage layer comprises an ion component and a metal component.

11. The electrochemical memory cell of claim 8, wherein at least one of the channel, the gate and the interface layer comprises a material generating an electrochemical reaction based on the gate voltage.

12. The electrochemical memory cell of claim 8, wherein at least one of the ion storage layer and the gate overlaps with the sidewalls and the upper surface of the channel.

13. A neural network memory device comprising:
a plurality of word lines extending parallel to each other along a first direction;
a plurality of bit lines extending parallel to each other along a second direction that intersects with the first direction;
a plurality of source lines extending parallel to at least one of the first direction and the second direction; and
an electrochemical memory cell arranged at intersected portions of the word lines, the bit lines and the source lines,
wherein the electrochemical memory cell comprises:
a protruded electrochemical fin structure;
a gate overlapped with a channel region of the protruded electrochemical fin structure and electrically connected to any one of the plurality of word lines;
a source formed in the protruded electrochemical fin structure at one side of the gate and electrically connected to any one of the plurality of source lines;
a drain formed in the protruded electrochemical fin structure at the other side of the gate and electrically connected to any one of the plurality of bit lines; and
an electrolyte layer between the channel region and the gate and contacting both sidewalls and an upper surface of the channel region.

14. The neural network memory device of claim 13, further comprising an ion storage layer interposed between the electrolyte layer and the gate and configured to generate and receive ions based on a gate voltage.

15. The neural network memory device of claim 14, wherein at least one of the ion storage layer and the gate overlaps with sidewalls and the upper surface of the channel region.

16. The neural network memory device of claim 13, wherein the electrolyte layer comprises an insulation material.
